(19) United States
(12) Patent Application Publication
(10) Pub. No.: US 2003/0075790 A1
(43) Pub. Date: Apr. 24, 2003

(54) Structure for aligning chips in stacked arrangement

(76) Inventors: Dan A. Steinberg, Blacksburg, VA (US); Arden Jeantilus, Orange, NJ (US)

Correspondence Address: BROWN, RUDNICK, BERLACK & ISRAELS, LLP., BOX IP, 18TH FLOOR, ONE FINANCIAL CENTER, BOSTON, MA, 02111, US

(21) Appl. No.: 10/218,105

(22) Filed: Aug. 12, 2002

Related U.S. Application Data
(63) Continuation of application No. 10/013,773, filed on Dec. 13, 2001.
(60) Provisional application No. 60/255,866, filed on Dec. 14, 2000.

(51) Int. Cl. G02B 6/32; H01L 23/02

(52) U.S. Cl. 257/686; 385/34

(57) ABSTRACT

An optical connector system is disclosed which utilizes a pair of substrates having optical elements associated therewith. Fiducial features in conjunction with alignment members are further utilized to provide for a greater alignment of the optical elements. Methods for forming the optical connector system are also provided.

### CROSS-REFERENCE TO RELATED APPLICATIONS

This application claims priority to U.S. Provisional Application Serial No. 60/255,866, filed Dec. 14, 2000 the contents of which are herein incorporated by reference.

### BACKGROUND

1. Technical Field

The present disclosure relates to a stacked chip structure. More particularly, this disclosure is directed to a structure for stacking chips in an accurate alignment without performing a backside alignment procedure on the bottom surface of the top chip.

2. Background of Related Art

In general, assemblies utilizing silicon include those which employ a frontside/frontside alignment. For example, as shown in FIG. 1, an optical assembly can be formed by employing two silicon substrates 10 and 30. Top substrate 10 has an optical element 12 and fiducials 14 and 16 formed in the bottom surface 11 of substrate 12 for receiving alignment spheres 18 and 20 with the bottom surface being patterned. Bottom substrate 30 has an optical element 32 and fiducials 34 and 36 formed in the top surface 31 of substrate 30 for receiving alignment spheres 18 and 20 with the top surface being patterned. The optical elements 12 and 32 associated with substrates 10 and 30 can be aligned by way of the alignment spheres 18 and 20 received in the respective fiducials of substrates 10 and 30. However, it is sometimes necessary to align an optical device on the upper surface of the top substrate with an optical device on the upper surface of the bottom substrate as, for example, when signals are transmitted through the substrate. Such an alignment can pose difficulties.

For example, as shown in FIG. 2, when a top substrate 100 has an optical element 120 formed in the top surface 130 of substrate 100 with the top surface being patterned instead of in the bottom surface, then a backside alignment procedure must be performed on the bottom surface 110 of substrate 100 to form fiducials 140 and 150 for receiving alignment spheres 160 and 170 to align-top substrate 100 with bottom substrate 30. Problems associated with this type of alignment procedure is that inaccurate alignment will result. Typically, this type of alignment procedure will be accurate to within only 5 microns. However, for micromechanical or microoptical devices, alignment of the substrates should be within about 1 micron or lower.

It would be desirable to provide a more accurate alignment of two substrates for forming an optical connector system without performing a backside alignment procedure on the bottom surface of the top substrate.

### SUMMARY

A stacked assembly is provided herein, the stacked assembly comprising first and second substrates, each having an upper surface and a lower surface. The first and second substrates are arranged in superposed, adjacent relation such that the lower surface of the first substrate is adjacent the upper surface of the second substrate. A first alignment rod is operatively associated with the upper surface of the first substrate. The stacked assembly includes means operatively associated with the upper surface of the second substrate for engaging the alignment rod such that the alignment rod and engaging means cooperate to arrange the first and second substrates at a predetermined orientation.

The stacked assembly provided herein advantageously can be formed by aligning the first substrate with the second substrate without performing a backside alignment procedure.

### BRIEF DESCRIPTION OF THE DRAWINGS

Various embodiments of the optical connector system of the present disclosure are described below with reference to the drawings wherein:

FIG. 1 is a schematic cross-sectional representation of a prior art alignment for a frontside-frontside alignment optical connector system;

FIG. 2 is a schematic cross-sectional representation of a prior art alignment for a frontside-backside alignment optical connector system;

FIG. 3 is a perspective view of one embodiment of the optical connector system in accordance with the present invention;

FIG. 4 is a top view of the optical connector system of FIG. 3;

FIG. 5 is a schematic cross-sectional view of a portion of the optical connector system of FIG. 3

FIG. 6 is a schematic cross-sectional view of an alternative elongated alignment member for forming the optical connector system of the present invention;

FIGS. 7-11 are top views of alternative embodiments of optical connector systems in accordance with the present invention;

FIG. 12 is an elevational view of an embodiment employing an alignment post;

FIG. 13 is a top view of an embodiment of the invention wherein the upper substrate has openings through which the alignment rods can engage alignment spheres; and,

FIG. 14 is a sectional view showing an embodiment wherein the alignment rods have been removed after assembly.

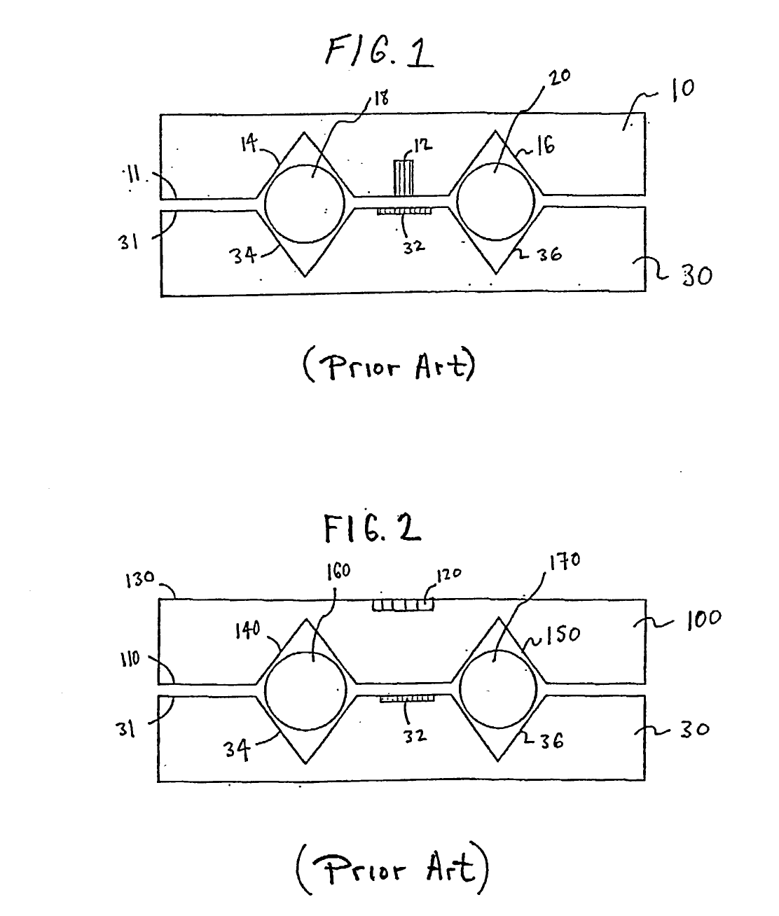

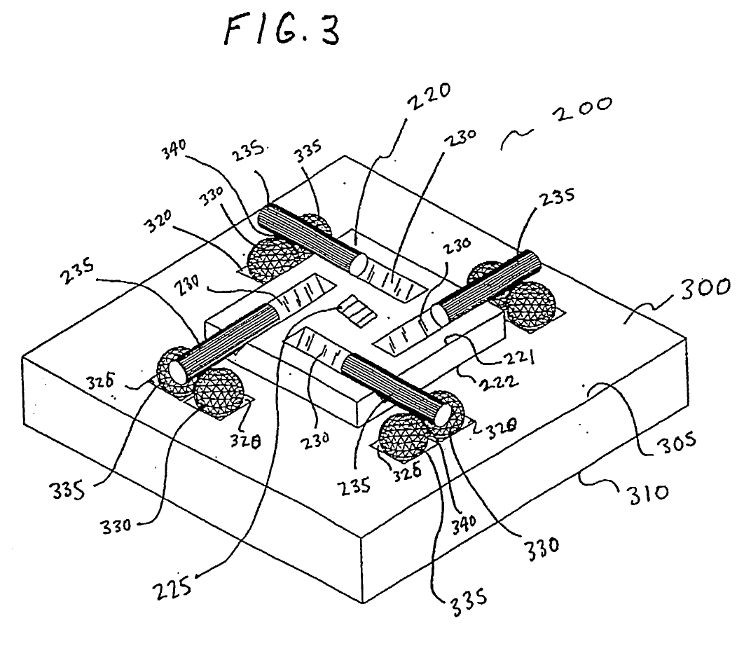

### DESCRIPTION OF THE PREFERRED EMBODIMENTS

As used herein such terms as “upper” and “lower” or “top” and “bottom” are used relative to each other and not to any external fixed frame of reference.

The present stacked assembly is useful for aligning a wide range of different signal communication elements. For example, the connector system described herein can be used to align fiber arrays or a fiber array and a micro lens array. The present invention can also be used to align, for example, micromachined substrates for micromechanical or microoptical devices.

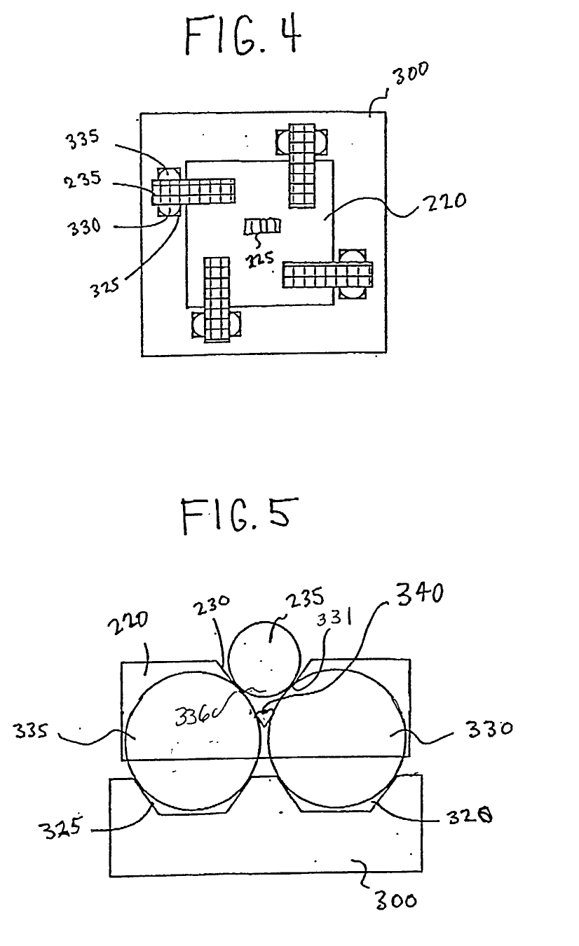

Turning now to the drawings, FIG. 3 illustrates, in perspective view, one embodiment in accordance with the present invention. FIG. 4 is a plan view of the embodiment shown in FIG. 3. Stacked assembly system 200 includes at least substrates 220 and 300 with substrate 300 having generally larger dimensions (e.g., length and width) than substrate 220. Substrates 220 and 300 can be any suitable material capable of being processed to form the requisite alignment fiducials therein, as discussed below. Suitable materials include, but are not limited to, silicon, gallium arsenide (GaAs), metals, polymeric materials such as, for example, a high-performance engineering plastic, and the like. Silicon is a preferred substrate material.

First substrate 220 is preferably fabricated from single crystal silicon and possesses a top surface 221 and bottom surface 222. Top surface 221 will generally include at least one elongated alignment fiducial 230 for receiving elongated alignment rod 235. The alignment fiducial 230 can be any feature (e.g., a ridge or groove, or a series of projections, etc.) which serves to orient the alignment rod 235 in a predetermined direction when engaged therewith. As shown herein, elongated alignment fiducial 230 is formed as grooves which extend along the top surface 221 of substrate 220 and terminates at the peripheral edge thereof. The groove 230 can be fabricated by employing well known etching techniques, e.g., anisotropic etching process utilizing a conventional anisotropic etchant known to those with skill in the art such as potassium hydroxide (KOH) or ethylene diamine pyrocatechol (EDP). In this manner, the depth and width of the V-groove is controlled with great precision. This enables a highly accurate passive alignment of substrate 220 with a second substrate 300 when elongated member 235 is received in gap 340 between alignment members 330 and 335 associated with substrate 300 as discussed below. Suitable alignment rods 235 can be formed from any conventional materials known in the art. Such materials include, but are not limited to, ceramics (e.g., silicon nitride, alumina, carbides, etc.), and metals (e.g., steel, titanium, etc., and the like). Alignment rod 235 is advantageously provided in the shape of cylindrical rods having circular cross sections to provide for more accurate alignment of substrate 220 with substrate 300. Alternatively, alignment rods 235 can have a prismatic configuration with triangular, square, hexagonal, or other polygonal cross sections, as well as oval cross sections.

The top surface 221 of substrate 220 can also include a signal communication element 225 mounted thereto for emitting, receiving, carrying, transmitting, or modifying a signal. Optionally, element 225 is an optical element such as, for example, a lens, filter, optical fiber, laser diode, photodetector, and the like.

Silicon substrate 300 possesses top surface 305 and bottom surface 310. Top surface 305 of substrate 300 includes means for engaging the alignment rod 235. Such means for engaging the alignment rod can be any member (or plurality of members) having one or more surfaces which can be contacted by the alignment rod and which cooperate with the alignment rod to maintain the substrate 200 in a fixed orientation relative to substrate 300. In the present embodiment the means for engaging the alignment rod include alignment members 330 and 335. The substrate 300 includes at least fiducials 320 and 325 for receiving alignment members 330 and 335, respectively. As discussed above, substrate 300 can be formed from the same or different materials as substrate 220.

Alignment members 330 and 335 have alignment surfaces 331 and 336, respectively, which are contacted by the alignment rod 235. If one imagines a vertical plane extending through the center of the alignment rod 235, alignment surfaces 331 and 336 contact the alignment rod 235 on opposite sides of the plane so as to cradle the alignment rod 235, holding the alignment rod in a predetermined orientation.

Fiducials 320 and 325 are configured and dimensioned to receive and align corresponding alignment members 330 and 335. The alignment members 330 and 335, in conjunction with alignment rod 235, provide alignment of the optical element of substrate 300 with the optical element of substrate 220. Techniques and parameters for forming fiducials 320 and 325 are within the purview of one skilled in the art (e.g., by anisotropic, isotropic, or dry etching of silicon). Fiducials 320 and 325 are adjacent to one another such that alignment members 330 and 335 are also adjacent one another.

Alignment members 330 and 335 are shown and described herein as spheres, although any other shape capable of performing the function described herein (e.g., cube, pyramid, rectangle, cylinder, etc.) is also contemplated as being within the scope of the invention. Alignment spheres 330 and 335 are highly precise balls fabricated from, for example, materials which include, but are not limited to, glass, ceramics, silicon nitride, alumina, carbides, metals (e.g., titanium, steel, aluminum, etc.), plastics, and the like. Alignment spheres 330 and 335 have a diameter optionally ranging from about 0.05 mm to about 2.0 mm and a diameter tolerance of optionally no more than about ±0.5 microns. Tolerance can vary depending on the material used to fabricate the alignment sphere. It will be recognized that the diameters of the alignment spheres can be outside the range given above without departing from the spirit or scope of the invention.

An advantageous feature of the method described herein is the self-centering nature of the alignment. For example, if the alignment spheres have a larger or smaller diameter than expected, the position along the Z-axis (i.e., a vertical axis) of the contact points between the alignment rod and the alignment spheres can be affected. But the X and Y axis positions (the location of the contact points in a lateral horizontal plane) is relatively unaffected. Usually, the Z-axis position of the contact points is not as critical as the lateral position. It should be noted that alignment spheres are usually made in large batches, and the alignment spheres within any single batch usually exhibit a high degree of consistency in diameter.

When substrate 220 and substrate 300 are assembled the bottom surface of substrate 220 is brought into facing relationship to the top surface of substrate 300 such that the alignment rod 235 is advantageously received in gap 340 between alignment spheres 330 and 335, and is in contact with the alignment spheres. FIG. 5 is a side view of a portion of the stacked assembly showing the engagement of the alignment rod and the spherical members 330 and 335.

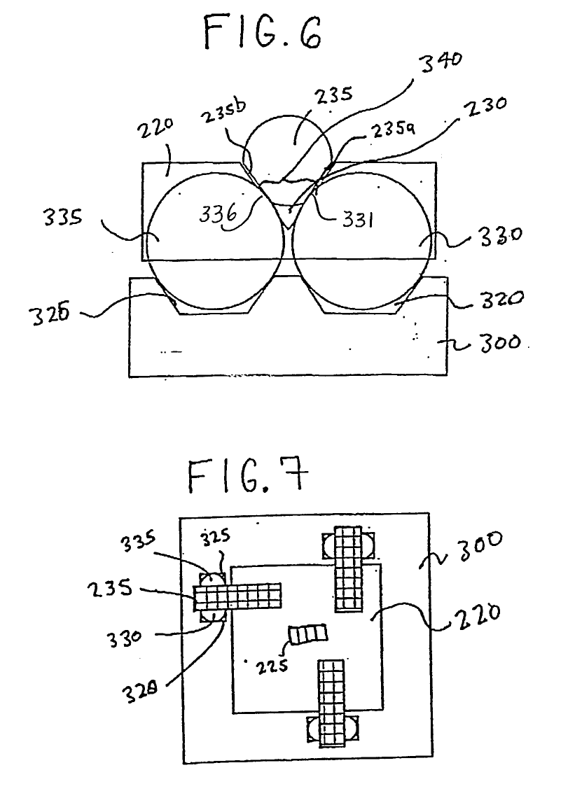

FIG. 6 shows an alternative embodiment 236 of an alignment rod having longitudinally extending flat surfaces 235a and 235b corresponding to and in contact with the side surfaces of the V-groove 230, and further in contact with alignment spheres 330 and 335 in gap 340.

Once alignment rod 235 is received in gap 340, alignment rod 235 can then be fixedly secured to alignment spheres 330 and 335 by employing any suitable attachment technique well known to one skilled in the art. These techniques such as soldering, brazing, use of bonding agents (e.g., epoxies or other monomeric or polymeric adhesives, sol gel glass, etc.), eutectic bonding, thermo-compression bonding, ultrasonic bonding, thermo-sonic bonding, or any other attachment technology known to those with ordinary skill in the art. These same technologies can be used to bond the alignment rod 235 to top substrate 220, and the alignment spheres 335 and bottom substrate 300. Likewise, when the substrates 220 and 300 are in a desired configuration, a bonding agent or other suitable bonding means can be used to securely fix the relative positions of the aligned substrates to prevent relative movement and to maintain the desired alignment.

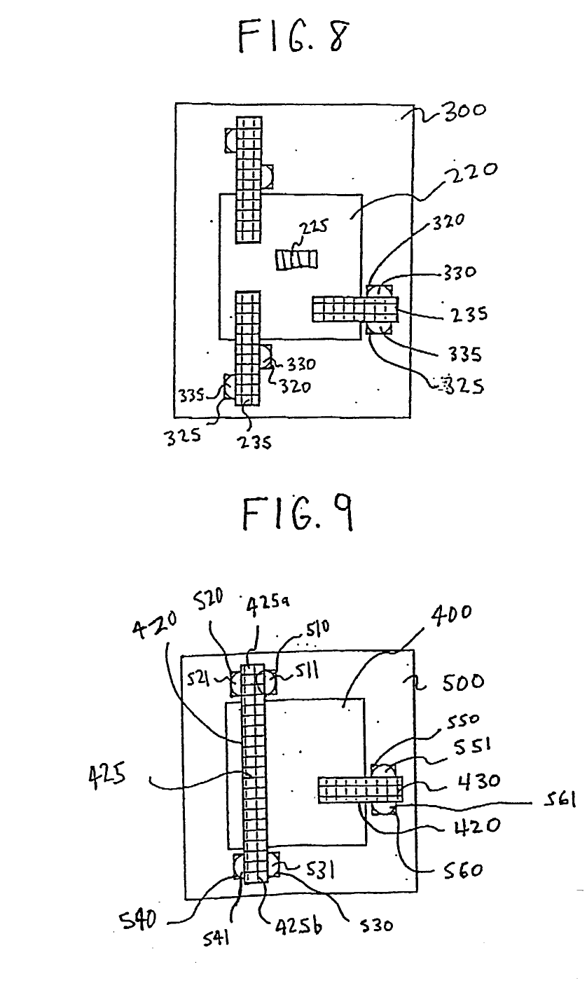

While FIGS. 3 and 4 illustrate alignment of substrates 220 and 300 utilizing four alignment rod 235 received in four sets of alignment spheres 330 and 335 arranged such that a stable mechanical attachment is achieved, it is to be understood that any suitable arrangement and number of elongated members 235 and spheres 330 and 335 may be utilized which results in a stable mounting of substrate 200. The mounting can optionally be kinematic in design. For example, referring to FIG. 7, three alignment rods 235 can be received in three sets of alignment spheres 330 and 335 to align substrate 220 with substrate 300. Other examples of alternative embodiments of the present invention are illustrated in FIGS. 8-11.

For example, FIG. 8 illustrates an optical connector system similar to that of FIG. 7 except that one or more set of fiducials (320, 325) are oriented along a diagonal direction relative to the substrate 300 for reception of alignment spheres 330 and 335.

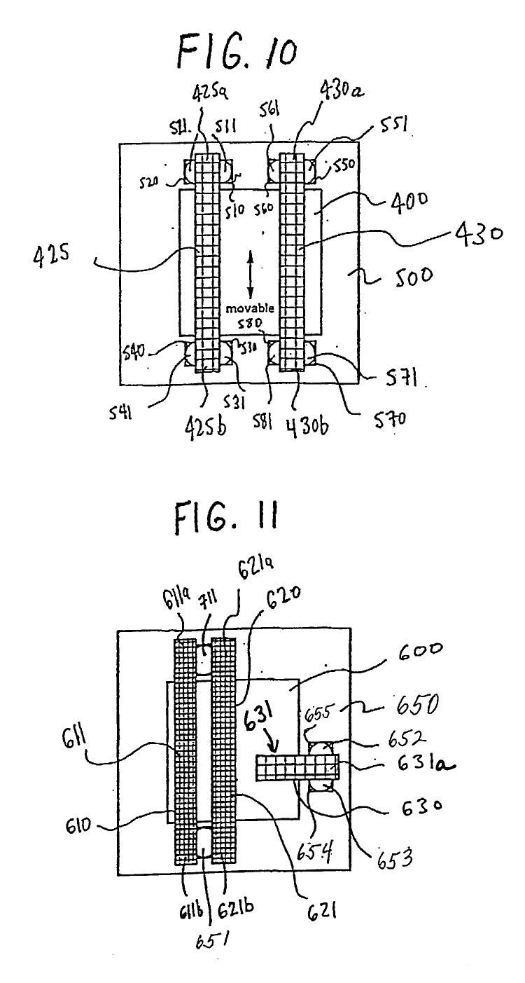

FIG. 9 shows an embodiment wherein alignment rods 425 and 430 are mounted within fiducial grooves 420 in substrate 400. However, alignment rod 425 has two opposite end portions 425a and 425b, which extend beyond the periphery of substrate 400. End portion 425a contacts alignment spheres 511 and 521, which are mounted to bottom substrate 500 in fiducials 510 and 520, respectively. End portion 425b contacts alignment spheres 531 and 541, which are mounted to bottom substrate 500 in fiducials 530 and 540, respectively. Alignment rod 430 is perpendicular to alignment rod 425 and has an end portion extending beyond the periphery of substrate 400. The end portion of alignment rod 430 contacts alignment spheres 551 and 561, which are mounted in fiducials 550 and 560, respectively in bottom substrate 500.

FIG. 10 shows an embodiment similar to that shown in FIG. 9 except that alignment rod 430 is oriented parallel to alignment rod 425 and has two opposite end portions 430a and 430b. End portion 430a contacts alignment spheres 551 and 561, which are mounted to bottom substrate 500 in fiducials 550 and 560, respectively. End portion 430b contacts alignment spheres 571 and 581, which are mounted to bottom substrate 500 in fiducials 570 and 580, respectively. Top substrate 400 can be movably adjusted in a linear direction parallel to the alignment rods 425 and 430.

FIG. 11 is a-top plan view illustrating an embodiment wherein top substrate 600 includes two spaced-apart alignment rods 611 and 621 which are parallel to each other, and an alignment rod 631 which is substantially perpendicular to the orientation of alignment rods 611 and 621. Alignment rod 611 is mounted in fiducial groove 610 and has two opposite end portions 611a and 611b, which extend beyond the peripheral edge of substrate 600. Alignment rod 621 is mounted in fiducial groove 620 and has two opposite end portions 621a and 621b, which extend beyond the peripheral edge of substrate 600. Alignment rod 631 is mounted in fiducial groove 630 and has an end portion 631a extending beyond the peripheral edge of substrate 600. End portions 611a and 621a contact opposite sides of a single alignment sphere 656, and end portions 611b and 621b contact opposite sides of alignment sphere 651. End portion 631a contacts two alignment spheres 652 and 653. Alignment sphere 652 is mounted within fiducial 655 in substrate 650 and alignment sphere 653 is mounted within fiducial 654 in substrate 650.

Referring to FIG. 12, optical connector system 700 includes a first substrate 710 having an alignment groove 713 on an upper surface 711. An alignment rod 730 is disposed in the alignment groove 713. Second substrate 720 includes an alignment post 725 having an alignment fiducial 723 defined by alignment surfaces 723a and 723b. The alignment rod 730 contacts the alignment surfaces 723a and 723b, and is held in a desired orientation, thereby aligning first substrate 710 and second substrate 720. Once aligned, substrates 710 and 720 can be fixedly secured in the desired orientation by a bonding agent or other suitable fixation means. Once the substrates are fixed in their position relative to each other, the alignment rod 730 can be removed, if desired, and reused to align another stacked substrate assembly. The alignment post 725 can be made in a silicon substrate by, for example, anisotropic etching with a suitable etchant (e.g., potassium hydroxide).

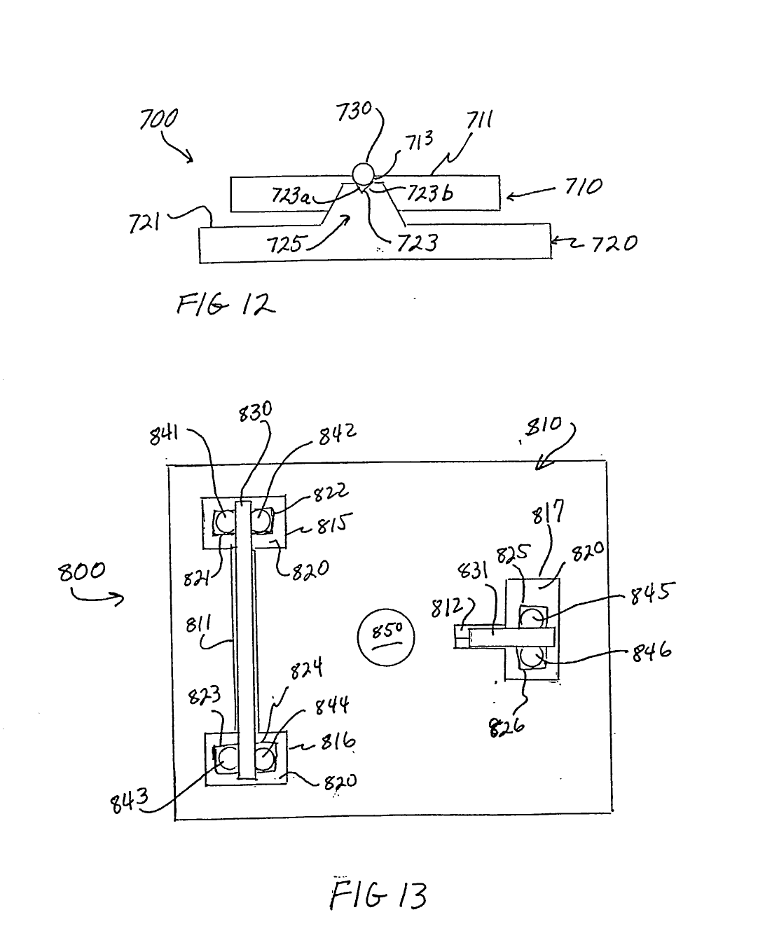

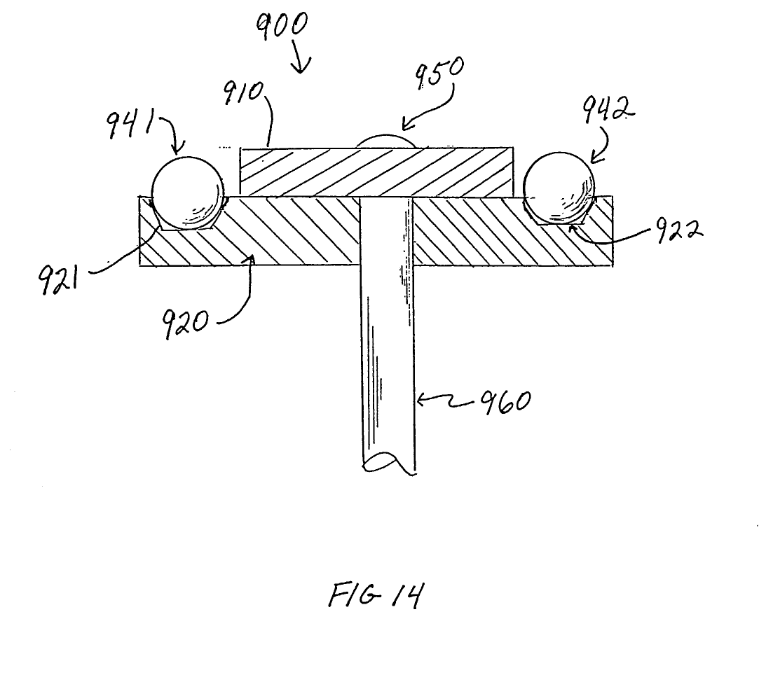

Referring now to FIG. 13, an optical device package 800 includes a first substrate 810 and a second substrate 820. First substrate 810 includes an upper surface having alignment grooves 811 and 812, and openings 815, 816, and 817 extending from the upper surface to the lower surface of substrate 810. Second substrate 820 includes fiducials 821 and 822 with alignment spheres 841 and 842 respectively positioned therein, fiducials 823 and 824 with alignment spheres 843 and 844 respectively positioned therein, and fiducials 825 and 826 with alignment spheres 845 and 846 respectively positioned therein. The fiducials and alignment spheres are positioned so as to align with corresponding openings 815, 816 and 817. Alignment rod 830 is disposed in groove 811, and the opposite end portions of alignment rod 830 laterally extend through openings 815 and 816 to contact alignment spheres 841 and 842 at one end, and alignment spheres 842 and 844 at the other end. Alignment rod 831 is positioned in alignment groove 812. One end portion of alignment rod 831 extends laterally through opening 817 to contact alignment spheres 845 and 846. An optical signal communication element, i.e., lens 850, is disposed on the upper surface of the first substrate 810. As can be seen, in this embodiment the first and second substrates 810 and 820 can be of the same dimensions of length and width without one substrate extending beyond the periphery of the other substrate.

Referring now to FIG. 14, an optical device package 900 includes a first substrate 910 having an upper surface with a lens 950, and a second substrate 920 fixedly secured to the first substrate 910 in an aligned configuration. Alignment spheres 941 and 942 are mounted respectively in fiducials 921 and 922 in the second substrate. An optical fiber 960 extends through the second substrate 920. An optical signal of appropriate wavelength (e.g., infrared) can be transmitted along an optical axis normal to the planes of substrates 910 and 920 from the optical fiber 960 through the silicon substrate 910 to lens 950. As can be seen, alignment rods, once used to align the substrates 910 and 920, can be omitted from the final optical device package 900 after the substrates 910 and 920 are fixed in the aligned relative positions by a suitable bonding agent or fixation means.

Although the invention has been described in its preferred formed with a certain degree of particularity, many changes and variations are possible therein and will be apparent to those skilled in the art after reading the foregoing description. For example, while the connector system has been described herein with respect to optical connectors, the present system can be used in other applications such as, for example, for semiconductor connectors. It is therefore to be understood that the present invention may be presented otherwise than as specifically described herein without departing from the spirit and scope thereof.

What is claimed is:

1. A stacked assembly comprising:
a first substrate having an upper surface and a lower surface;
a second substrate having an upper surface and a lower surface,
the first and second substrates being arranged in superposed, adjacent relation such that the lower surface of the first substrate is adjacent the upper surface of the second substrate;
a first alignment rod operatively associated with the upper surface of the first substrate; and
means operatively associated with the upper surface of the second substrate for engaging the first alignment rod, said alignment rod and engaging means cooperating to arrange the first and second substrates at a predetermined orientation.

2. The stacked assembly of claim 1 further comprising:
a first signal communication element associated with the first substrate for emitting, receiving, carrying or modifying a signal,
a second signal communication element associated with the second substrate for emitting, receiving, carrying or modifying a signal,
the first alignment rod and engaging means cooperating to arrange the first and second substrates such that the first and second signal communication elements are in operative alignment with each other.

3. The stacked assembly of claim 2 wherein the first and-second signal communication elements are optical elements.

4. The stacked assembly of claim 3 wherein the optical elements are selected from the group consisting of a lens, filter, optical fiber, laser diode and photodetector.

5. The stacked assembly of claim 1 wherein the first alignment rod includes a first end portion extending beyond a peripheral edge of the first substrate.

6. The stacked assembly of claim 5 wherein the engaging means comprises as least one spherical member fixedly mounted to the second substrate, wherein the first end portion of the first alignment rod contacts a portion of the surface of the sphere.

7. The stacked assembly of claim 6 wherein the engaging means comprises a first pair of spherical members, the first end portion of the first alignment rod being disposed between and in contact with both of the spherical members.

8. The stacked assembly of claim 7 wherein the first alignment rod includes a second end portion opposite the first end portion, and the engaging means comprises a second pair of spherical members, the second end portion of the first alignment rod being disposed between and in contact with the second pair of spherical members.

9. The stacked assembly of claim 1 further including a second alignment rod parallel to the first alignment rod, the first alignment rod and second alignment rod each having first and second end portions extending beyond a peripheral edge of the first substrate.

10. The stacked assembly of claim 9 wherein the engaging means comprises a first spherical member mounted to the second substrate and being positioned between and in contact with the first end portions of the first and second alignment rods, and a second spherical member mounted to the second substrate and positioned between and in contact with the second end portions of the first and second substrates.

11. The stacked assembly of claim 9 wherein the engaging means comprises first, second, third and fourth pairs of spherical members, the first end portion of the first alignment rod being disposed between and in contact with the first pair of spherical members, the second end portion of the first alignment rod being disposed between and in contact with the second pair of spherical members, the first end portion of the second alignment rod being disposed between and in contact with the third pair of spherical members, and the second end portion of the second alignment rod being disposed between and in contact with the fourth pair of spherical members.

12. The stacked assembly of claim 1 comprising a second alignment rod oriented perpendicular to the orientation of the first alignment rod.

13. The stacked assembly of claim 1 wherein the first alignment rod has at least one longitudinally extending flat surface.

14. The stacked assembly of claim 1 comprising first second third and fourth alignment rods, each alignment rod having an end portion extending beyond a respective side of the first substrate and disposed between and in contact with a respective pair of spherical members.

15. The stacked assembly of claim 1 wherein the first and second substrates are fabricated from single crystal silicon.

16. An optical system which comprises:
a first substrate having an upper surface with at least two alignment grooves, a lower surface, and a first optical element mounted to the upper surface of the first substrate;
a second substrate having an upper surface with at least two pairs of alignment surfaces associated therewith, a lower surface, and a second optical element mounted to the upper surface of the second substrate.
the first and second substrates being arranged in superposed, adjacent relation such that the lower surface of the first substrate is adjacent the upper surface of the second substrate, the alignment grooves of the upper surface of the first substrate being aligned with respective pairs of alignment surfaces of the second substrate.

17. The optical assembly of claim 15 wherein the first and second optical elements are selected from the group consisting of a lens, filter, optical fiber, laser diode and photodetector.

18. The optical assembly of claim 15 further comprising an alignment rod in a respective one of each of the alignment grooves, wherein the alignment rods engage a respective pair of the alignment surfaces of the second substrate.

19. A method for manufacturing an optical system having first and second substrates with optical elements associated therewith, comprising the steps of:
positioning the first and second substrates in adjacent superposed relation, each said first and second substrates having upper and lower surfaces; and
operatively interconnecting alignment members associated with said upper surfaces of said first and second substrates to arrange said first and second substrates at a predetermined orientation to substantially optically align said optical elements thereof.

20. The method of claim 19 wherein the first substrate includes a pair of first alignment members operatively connected to said upper surface of said first substrate and said second substrate includes a second alignment member operatively connected to said upper surface of said second substrate and wherein the step of operatively interconnecting includes at least partially positioning said second alignment member within a passage defined by said pair of said first alignment members.

21. The method of claim 20 wherein said pair of first alignment members are operatively connected to said upper surface of said first substrate by a bonding technique selected from the group consisting of soldering, brazing, applying an adhesives, sol gel glass bonding, eutectic bonding, thermo-compression bonding, ultrasonic bonding or thermo-sonic bonding.

22. The method of claim 20 wherein said second alignment member is operatively connected to said upper surface of said second substrate by a bonding technique selected from the group consisting of soldering, brazing, applying an adhesives, sol gel glass bonding, eutectic bonding, thermo-compression bonding, ultrasonic bonding or thermo-sonic bonding.
